(19) United States
(12) Patent Application Publication
(10) Pub. No.: US 2026/0258280 A1
(43) Pub. Date: Sep. 3, 2026

(54) SILICON-CONTAINING FILM FORMING COMPOSITION AND METHOD FOR MANUFACTURING SILICON-CONTAINING FILM USING THE SAME

(71) Applicant: MERCK PATENT GMBH, DARMSTADT (DE)

(72) Inventors: NAOKO NAKAMOTO, SHIZUOKA (JP); HIDEYUKI TAKAGISHI, SHIZUOKA (JP); TAKASHI FUJIWARA, SHIZUOKA (JP); ATSUHIKO SATO, SHIZUOKA (JP)

(21) Appl. No.: 18/715,040

(22) PCT Filed: Nov. 28, 2022
(86) PCT No.: PCT/EP2022/083415

§ 371 Date: Oct. 10, 2024

(30) Foreign Application Priority Data
Nov. 30, 2021 (JP) 2021-194812

(51) Int. Cl. C09D 183/16; B05D 1/00; B05D 3/02; B05D 3/06

(52) U.S. Cl. CPC C09D 183/16; B05D 1/005; B05D 3/0254; B05D 3/065; B05D 2203/30; B05D 2518/12

(57) ABSTRACT

A silicon-containing film forming composition comprising (I) a polymer having a polysilane skeleton comprising a particular repeating unit, (II) a silicon compound having an unsaturated hydrocarbon bond, and (III) a solvent.

### CROSS-REFERENCE TO RELATED APPLICATIONS

This application for a patent is a National Stage filing under 35 U.S.C. 371 of International Application No. PCT/EP2022/083415, filed Nov. 28, 2022, which claims priority to the Japanese Patent Application No. 2021-194812, filed Nov. 30, 2021. Both applications are hereby incorporated in this application in their entirety.

### BACKGROUND OF THE INVENTION

### Technical Field

The present invention relates to a silicon-containing film forming composition and a method for manufacturing a silicon-containing film using the same.

### Background Art

Electronic devices, particularly semiconductor devices, are composed of thin films such as semiconductor films, insulating films and conductive films. The silicon-containing film is used as a semiconductor film, as an etching mask during processing of an insulating film, and as a sacrificial film during manufacturing a metal gate and the like.

Methods for forming an amorphous silicon film or a polycrystalline silicon film include, for example, a chemical vapor deposition method (CVD method), a vapor deposition method, a sputtering method, or the like. At an advanced node, if a vapor phase process such as CVD is used, excessive growth is caused in a narrow trench, and etching and CVD need to be repeated. Therefore, it has been studied to form a film by applying a liquid composition comprising a silicon-containing polymer and baking it.

Polysilanes, such as hydrogenated polysilanes, are known silicon-containing polymers, but a liquid composition containing the hydrogenated polysilane often has a low affinity for a substrate, and cases in which a film can be formed using hydrogenated polysilanes are extremely limited.

In order to add functionality to polysilane, studies to introduce a specific functional group have been conducted. For example, JP2002-128897 A discloses a method for producing a polysilane copolymer by reacting a halosilane compound with a vinyl compound.

### SUMMARY OF THE INVENTION

### Problems to be Solved by the Invention

The present invention has been made based on the background technology as described above, and provides a silicon-containing film forming composition having a high affinity for a substrate.

### Means for Solving the Problems

The silicon-containing film forming composition according to the present invention comprises:
(I) a polymer having a polysilane skeleton comprising a repeating unit represented by the formula (ia):

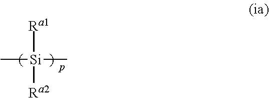

wherein
R^{a1} and R^{a2} are each independently a single bond, hydrogen, halogen, C1-6 alkyl, C6-10 aryl or —SiR^{A}₃ (where R^{A} is each independently hydrogen or C1-8 alkyl), and
p is an integer of 5 or more;
(II) a silicon compound having an unsaturated hydrocarbon bond; and
(III) a solvent.

A method for manufacturing a silicon-containing film according to the present invention comprises:
applying the above-mentioned silicon-containing film forming composition above a substrate to form a coating film, and heating the coating film.

A method for manufacturing an electronic device according to the present invention comprises the above-mentioned method for manufacturing a silicon-containing film.

### Effects of the Invention

The silicon-containing film forming composition according to the present invention has a high affinity for a substrate, and has good coatability and adhesion to the substrate. The silicon-containing film formed using the silicon-containing film forming composition according to the present invention has low residual stress.

### DETAILED DESCRIPTION OF THE INVENTION

### Mode for Carrying Out the Invention

### Definition

Unless otherwise specified in the present specification, the definitions and examples described in this paragraph are as follows.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

“Alkyl” means a group obtained by removing any one hydrogen from a linear, branched or cyclic saturated hydrocarbon, and it includes a linear alkyl, branched alkyl and cyclic alkyl, and the cyclic structure contains a linear or branched alkyl as a side chain, if necessary. “Aryl” means a group obtained by removing any one hydrogen from an aromatic hydrocarbon.

The descriptions such as “Cx-y”, “Cx-Cy” and “Cx” mean the number of carbons in a molecule or substituent. For example, C1-6 alkyl means an alkyl chain having 1 or more and 6 or less carbons (methyl, ethyl, propyl, butyl, pentyl, hexyl etc.).

When a polymer has plural types of repeating units, these repeating units copolymerize. These copolymerizations are any of alternating copolymerization, random copolymerization, block copolymerization, graft copolymerization, or a mixture thereof. When a polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent (III) or another component.

Hereinafter, embodiments of the present invention are described in detail.

### <Silicon-Containing Film Forming Composition>

The silicon-containing film forming composition according to the present invention (hereinafter, referred to as the composition) comprises (I) a polymer having a polysilane skeleton having a particular structure, (II) a silicon compound having an unsaturated hydrocarbon bond, and (III) a solvent.

### Polymer Having a Polysilane Skeleton

The composition according to the present invention comprises a polymer having a polysilane skeleton comprising a repeating unit represented by the formula (ia) (hereinafter, referred to as the polymer having a polysilane skeleton, the polymer, or the component (I)).

The formula (ia) is as follows:

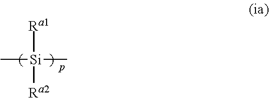

wherein
R^{a1} and R^{a2} are each independently a single bond, hydrogen, halogen, C1-6 alkyl, C6-10 aryl or —SiR^{A}₃, preferably a single bond, hydrogen or —SiR^{A}₃, and more preferably hydrogen. When Ra1 and Ra2 are a single bond, they are bonded to a single bond in another repeating unit represented by the formula (ia) or a repeating unit represented by the formula (ib) in the polymer, and directly combines each silicon to which they are bonded. Each Ra1 can be the same or different, and each Ra2 can be the same or different. In a preferred embodiment of the present invention, Ra1 and Ra2 are the same. In another embodiment of the present invention, Ra1 and Ra2 are different.
   R^{A} is each independently hydrogen or C1-8 alkyl, preferably hydrogen or methyl, and more preferably hydrogen.
   p is an integer of 5 or more, preferably 5 to 20, and more preferably 6 to 10.

The polymer having a polysilane skeleton used in the present invention preferably further comprises a repeating unit represented by the formula (ib).

The formula (ib) is as follows:

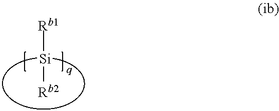

wherein
Rb1 and Rb2 is each independently a single bond, hydrogen, halogen, C1-6 alkyl, C6-10 aryl or —SiR^{B}₃, preferably single bond, hydrogen or —SiR^{B}₃, and more preferably hydrogen or a single bond, provided that at least one of Rb1 and Rb2 is a single bond. When Rb1 and Rb2 are a single bond, it is bonded to a single bond in another repeating unit represented by the formula (ib) or a repeating unit represented by the formula (ia) in the polymer, and directly combines each silicon to which they are bonded.
   R^{B} is each independently hydrogen or C1-8 alkyl, preferably hydrogen or methyl, and more preferably hydrogen.
   q is an integer of 5 or more, preferably 5 to 12, and more preferably 6.

Exemplified embodiments of the polymer having a polysilane skeleton include the following.

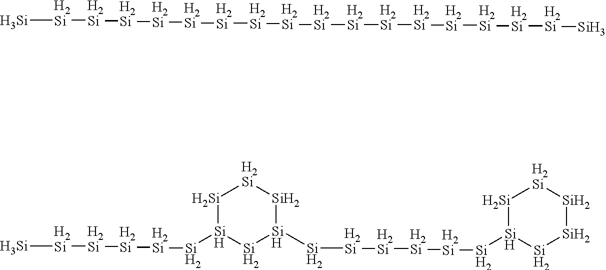

It is also one preferred embodiment of the present invention that the polymer having a polysilane skeleton does not have any Si—C bond. By not having any Si—C bond, etching with an alkaline solution becomes easier after forming a film, and processability can be improved.

The mass average molecular weight of the polymer having a polysilane skeleton is preferably 500 to 20,000, more preferably 1,000 to 15,000, for reasons of solubility in a solvent, planarity of the formed film, and adhesion to a substrate. The mass average molecular weight is a mass average molecular weight in terms of polystyrene, and can be measured by the gel permeation chromatography based on polystyrene.

The polymer having a polysilane skeleton is preferably a polymer of a polysilane compound comprising 5 or more of silicon (hereinafter, referred to as the polysilane compound). In a preferred embodiment, the polymer having a polysilane skeleton is formed by polymerizing the polysilane compound by light irradiation and/or heating.

The number of silicon atoms contained in the polysilane compound is preferably 5 to 8, and more preferably 5 or 6. The polysilane compound can be an inorganic compound or an organic compound, and can have a linear, branched or partially cyclic structure.

The polysilane compound can be one kind or a mixture of two or more kinds, preferably comprising a cyclic polysilane, and more preferably consisting of a cyclic polysilane.

The cyclic polysilane is preferably represented by the following formula (ib′).

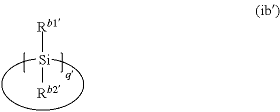

wherein
Rb1′ and Rb2′ are each independently hydrogen, halogen, C1-6 alkyl, C6-10 aryl or —SiR^{B′}₃, preferably hydrogen or silyl, and more preferably hydrogen.
R^{B′} is each independently hydrogen or C1-8 alkyl, preferably hydrogen or methyl, and more preferably hydrogen.
q′ is an integer of 5 or more, preferably 5 to 8, and more preferably 5 or 6.

The cyclic polysilane is preferably at least one selected from the group consisting of silylcyclopentasilane, silylcyclohexasilane, disilylcyclohexasilane, cyclopentasilane and cyclohexasilane, and is more preferably cyclohexasilane and cyclopentasilane.

The polysilane compound can contain linear or branched polysilane, and examples of the linear or branched polysilane include neopentasilane, hexasilane, 3-silylpentasilane, 2,2-disilyltetrasilane, heptasilane, tetrasilyltetrasilane and hexasilylpentasilane. It is one preferred embodiment of the present invention that at least one of these are contained.

The above polysilane compound is preferably polymerized by light irradiation and/or heating, and more preferably by light irradiation.

In the case of light irradiation, the peak wavelength is preferably 248 to 436 nm, more preferably 282 to 405 nm. The irradiation intensity is preferably 10 to 250 mW/cm2, more preferably 50 to 150 mW/cm2, and the irradiation time is preferably 30 to 300 seconds, more preferably 50 to 200 seconds.

In the case of heating, it is preferable to conduct at 40 to 200° C. for 3 to 300 minutes.

It is also preferable to combine the above light irradiation and heating. It is assumed that when the polysilane compound contains a cyclic polysilane, a part or all of the cyclic polysilane is ring-opened by light irradiation and/or heating in this step. A cyclic polysilane structure that is not ring-opened can be contained in the polymer having a polysilane skeleton.

The component (I) can be a mixture of two or more kinds.

The content of the component (I) is 2.0 to 30.0 mass %, and more preferably 5.0 to 25.0 mass %, based on the total mass of the composition. (II) Silicon compound having an unsaturated hydrocarbon bond.

The composition according to the present invention comprises a silicon compound having an unsaturated hydrocarbon bond (hereinafter, referred to as the component (II)). The same apply to other components.

When the composition according to the present composition comprises the component (II), the affinity with the substrate is increased, and the coatability and adhesion to the substrate are improved. As a result, a uniform coating film can be formed on the substrate. Although this is not wishing to be bound by theory, it may be because that the silicon compound having an unsaturated hydrocarbon bond and the polymer having a polysilane skeleton form a bond, and the bonded silicon compound having an unsaturated hydrocarbon bond forms a bond with a hydroxy group or the like on the surface of the substrate.

Further, when the composition according to the present composition comprises the component (II), the residual stress of the formed silicon-containing film can be reduced. Although this is not wishing to be bound by theory, it may be because that the hydrocarbon of the silicon compound having an unsaturated hydrocarbon bond inhibits the formation of a three dimensionally formed silicon-containing network.

Further, when the composition according to the present composition comprises the component (II), the refractive index of the formed silicon-containing film can be lowered. Although this is not wishing to be bound by theory, it may be because that the carbon of the silicon compound having an unsaturated hydrocarbon bond forms local hydrocarbon or graphite in the silicon-containing film.

The component (II) has at least one carbon-carbon double bond or carbon-carbon triple bond, preferably two or more carbon-carbon double bond. Preferably, the component (II) has unsaturated hydrocarbon bond at its terminal. More preferably, the component (II) has two or more vinyl groups, and further more preferably 2 to 4 vinyl groups.

In a preferred embodiment, the component (II) is represented by the formula (ii).

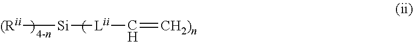

wherein
Lⁱⁱ is each independently a single bond or C1-5 alkylene, preferably a single bond, methylene or ethylene, and more preferably a single bond.
Rⁱⁱ is each independently hydrogen or C1-5 alkyl, preferably hydrogen, methyl or ethyl, and more preferably methyl.
n is 1, 2, 3 or 4, preferably 2, 3 or 4, and more preferably 4.

Preferably, the component (II) is at least one selected from the group consisting of divinylsilane, trivinylsilane, tetravinylsilane, methyldivinylsilane, dimethyldivinylsilane, methyltrivinylsilane, diallylsilane, triallylsilane, diallylmethylsilane, diallyldimethylsilane, triallylmethylsilane, and tetraallylsilane.

The molecular weight of the component (II) is preferably 50 to 300, and more preferably 80 to 200. The component (II) can be a mixture of two or more kinds. The content of the component (II) is 0.20 to 10.0 mass %, and more preferably 0.40 to 7.0 mass %, based on the total mass of the composition.

### (III) Solvent

The composition according to the present invention comprises a solvent. The solvent is selected from those which uniformly dissolve or disperse each component contained in the composition. Exemplified embodiments of the solvent include ethylene glycol monoalkyl ethers, such as ethylene glycol monomethyl ether, ethylene glycol monoethyl ether, ethylene glycol monopropyl ether and ethylene glycol monobutyl ether; diethylene glycol dialkyl ethers, such as diethylene glycol dimethyl ether, diethylene glycol diethyl ether, diethylene glycol dipropyl ether and diethylene glycol dibutyl ether; ethylene glycol alkyl ether acetates, such as methyl cellosolve acetate and ethyl cellosolve acetate; propylene glycol monoalkyl ethers, such as propylene glycol monomethyl ether (PGME) and propylene glycol monoethyl ether; propylene glycol alkyl ether acetates such as propylene glycol monomethyl ether acetate (PGMEA), propylene glycol monoethyl ether acetate and propylene glycol monopropyl ether acetate; aromatic hydrocarbons, such as benzene, toluene, xylene and mesitylene; ketones, such as methyl ethyl ketone, acetone, methyl amyl ketone, methyl isobutyl ketone and cyclohexanone; alcohols, such as isopropanol and propanediol; and alicyclic hydrocarbons, such as cyclooctane and decalin. Preferred are cyclooctane, toluene, decalin and mesitylene.

These solvents can be used alone or in combination of two or more of any of these.

In order to homogeneously dissolve polysilane, the relative dielectric constant of the solvent is preferably 3.0 or less, more preferably 2.5 or less on the basis of the value described in “Solvent Handbook, 1st Edition”, Kodansha Scientific.

Although the mixing ratio of the solvent varies depending on the coating method and the film thickness after coating, the ratio (solid content ratio) of the compounds other than the solvent is 1 to 96 mass %, and preferably 2 to 60 mass %.

### (IV) Polysilazane

The composition according to the present invention can further comprise (IV) a polysilazane. When a polysilazane is further comprised in the composition, the coatability can be improved, and the planarity of the formed silicon-containing film can be improved.

The polysilazane can be freely selected unless it impairs the effect of the present invention. These are either inorganic compounds or organic compounds, and can be linear, branched, or partially having a cyclic structure.

Preferably, the polysilazane used in the present invention comprises at least 20, preferably 20 to 350, and more preferably 20 to 130, repeating units selected from the group consisting of the following formulae (iv-1) to (iv-6). In this case, it is preferable that each repeating unit is directly bonded to each other without using repeating unit other than (iv-1) to (iv-6).

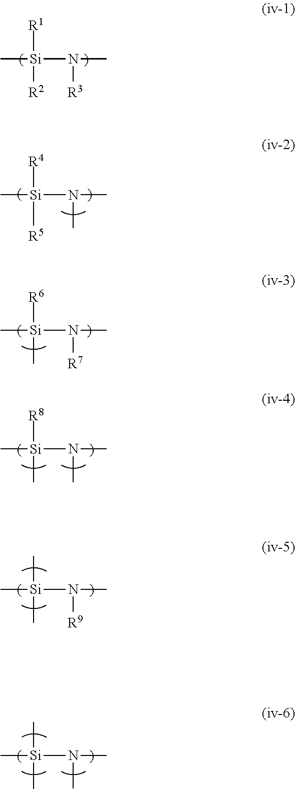

wherein R1 to R9 are each independently hydrogen or C1-4 alkyl.

More preferably, the polysilazane used in the present invention is perhydropolysilazane (hereinafter referred to as “PHPS”). PHPS is a silicon-containing polymer comprising Si—N bonds as repeating units and consisting only of Si, N and H. PHPS includes Si—N bonds as a repeating unit, and is a polymer consisting of Si, N and H. In this PHPS, except Si—N bond, all elements binding to Si or N are H and any other elements such as carbon or oxygen are not substantially contained. The simplest structure of the perhydropolysilazane is a chain structure having a repeating unit of the following formula.

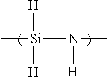

In the present invention, any PHPS having a chain structure and a cyclic structure in the molecule can be used, and examples of the PHPS include those comprising repeating units represented by the following formulae (iv-a) to (iv-f) and a terminal group represented by the following formula (iv-g) in the molecule.

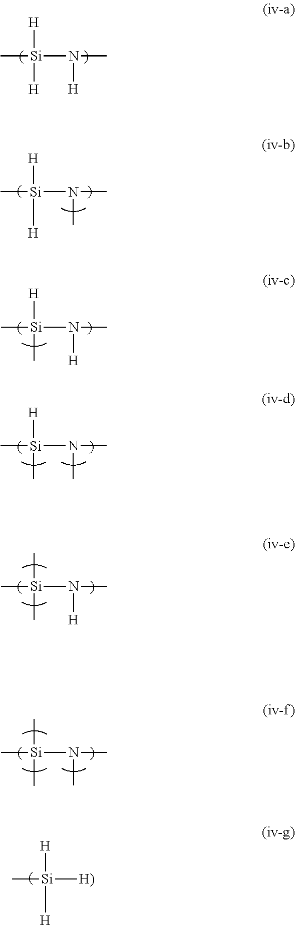

Such a PHPS is one having a branched structure or a cyclic structure in the molecule, and an example of a specific partial structure of such a PHPS is one represented by the following formula.

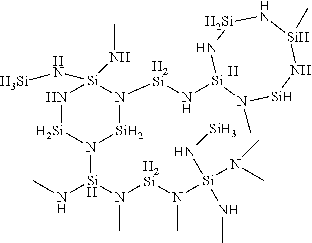

Further, it has or has not a structure represented by the following formula, i.e. a structure wherein plural Si—N molecular chains are crosslinked.

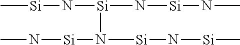

As far as the PHPS used in the present invention comprises Si—N bonds as the repeating unit and is a silicon-containing polymer consisting only of Si, N and H, its structure is not limited, and other various structures exemplified above are possible. For example, it can be one having a structure composed by combining the above-described linear structure, cyclic structure, and crosslinked structure. The PHPS used in the present invention is preferably one having a cyclic structure or crosslinked structure, particularly crosslinked structure.

From the viewpoint of the solubility in solvents and the reactivity, the mass average molecular weight of the polysilazane used in the production method according to the present invention is preferably 900 to 15,000, and more preferably 900 to 10,000. The mass average molecular weight is a mass average molecular weight in terms of polystyrene, and it can be measured by gel permeation chromatography based on polystyrene.

The content of the component (IV) is preferably 0 to 5.0 mass %, and more preferably 0.50 to 3.0 mass %, based on the total mass of the composition.

The composition used in the present invention can comprise further compounds, if necessary. The materials which can be comprised are described below. The components other than (I) to (IV) contained in the whole composition are preferably 10% or less, and more preferably 5% or less, based on the total mass.

Surfactant can be used because it can improve the coatability. Examples of the surfactant include nonionic surfactants, anionic surfactants, amphoteric surfactants, and the like.

Examples of the nonionic surfactant include, polyoxyethylene alkyl ethers, such as polyoxyethylene lauryl ether, polyoxyethylene oleyl ether and polyoxyethylene cetyl ether; polyoxyethylene fatty acid diester; polyoxyethylene fatty acid monoester; polyoxyethylene polyoxypropylene block polymer; acetylene alcohol; acetylene glycols; acetylene alcohol derivatives, such as polyethoxylate of acetylene alcohol; acetylene glycol derivatives, such as polyethoxylate of acetylene glycol; fluorine-containing surfactants, for example, FLUORAD (trade name, manufactured by 3M Japan Limited), MEGAFACE (trade name: manufactured by DIC Cooperation), SURFLON (trade name, manufactured by AGC Inc.); or organosiloxane surfactants, for example, KP341 (trade name, manufactured by Shin-Etsu Chemical Co., Ltd.), and the like. Examples of said acetylene glycol include 3-methyl-1-butyne-3-ol, 3-methyl-1-pentyn-3-ol, 3,6-dimethyl-4-octyne-3,6-diol, 2,4,7,9-tetramethyl-5-decyne-4,7-diol, 3,5-dimethyl-1-hexyne-3-ol, 2,5-dimethyl-3-hexyne-2,5-diol, 2,5-dimethyl-2,5-hexane-diol, and the like.

Examples of the anionic surfactant include ammonium salt or organic amine salt of alkyl diphenyl ether disulfonic acid, ammonium salt or organic amine salt of alkyl diphenyl ether sulfonic acid, ammonium salt or organic amine salt of alkyl benzene sulfonic acid, ammonium salt or organic amine salt of polyoxyethylene alkyl ether sulfuric acid, ammonium salt or organic amine salt of alkyl sulfuric acid, and the like.

Examples of the amphoteric surfactant include 2-alkyl-N-carboxymethyl-N-hydroxyethyl imidazolium betaine, lauric acid amide propyl hydroxysulfone betaine, and the like.

These surfactants can be used alone or in combination of two or more of any of these, and the mixing ratio thereof is usually 50 to 10,000 ppm, and preferably 100 to 5,000 ppm, based on the total mass of the composition.

### <Method for Preparing a Silicon-Containing Film Forming Composition>

The method for preparing a silicon-containing film forming composition according to the present invention is not particularly limited.

When the polymer having a polysilane skeleton is a polymer of the cyclic polysilane containing 5 or more silicon, it is manufactured, for example, by a method comprising:
(A) a step of irradiating the cyclic polysilane containing 5 or more silicon with light,
(B) a step of preparing a mixture comprising the silicon compound having an unsaturated hydrocarbon bond used in the present invention, and
(C) a step of irradiating the mixture with light.

Hereinafter, one example of the manufacturing method is described with respect to each step.

The wavelength of the step (A) preferably comprises a peak wavelength of at least 172 to 405 nm, and more preferably 282 to 405 nm. The irradiation intensity is preferably 10 to 250 mW/cm2, more preferably 50 to 150 mW/cm2, and the irradiation time is preferably 30 to 300 seconds, more preferably 50 to 200 seconds.

Since cyclopentasilane or cyclohexasilane is liquid at room temperature, the cyclic polysilane in a liquid state can be irradiated with light while stirring. When the cyclic polysilane is a solid, it can be dissolved in any appropriate solvent and irradiated with light while stirring.

It is assumed that a part or all of the cyclic polysilane is ring-opened by the light irradiation in this step.

### (B) Step of Preparing a Mixture Comprising the Silicon Compound Having an Unsaturated Hydrocarbon Bond Used in the Present Invention

When the cyclic polysilane irradiated with light is in a liquid state at room temperature, the above-mentioned silicon compound having an unsaturated hydrocarbon bond is added thereto and stirred, thereby preparing a mixture. When the cyclic polysilane irradiated with light is a solid, it can be dissolved in an appropriate solvent. It is also possible that the silicon compound having an unsaturated hydrocarbon bond is dissolved in an appropriate solvent, then added to the cyclic polysilane irradiated with light, and stirred, thereby preparing a mixture.

(C) Step of Irradiating the Mixture with Light

It is assumed that by the light irradiation in this step, condensation of each polysilane is caused to form a polymer having a polysilane skeleton.

The exposure wavelength at this time preferably comprises a peak wavelength of at least 172 to 405 nm, and more preferably 282 to 405 nm. The irradiation intensity is preferably 10 to 250 mW/cm2, more preferably 50 to 150 mW/cm2, and the irradiation time is preferably 5 to 100 minutes, more preferably 5 to 60 minutes. The irradiation energy is preferably 3 to 1,500 J, more preferably 25 to 500 J. In addition, the order of the steps (B) and (C) can be reversed. That is, after the step (A), the light irradiation described in the step (C) can be performed, and then the silicon compound having an unsaturated hydrocarbon bond can be added to prepare a mixture.

The above steps (A), (B) and (C) are preferably performed in a non-oxidizing atmosphere.

The solvent can be added in the step (A) or (B) as described above, or can be added after the step (C). It is preferable that the above-mentioned optional component is added after the step (C).

### <Method for Manufacturing a Silicon-Containing Film>

The method for manufacturing a silicon-containing film according to the present invention comprises:
applying the above-mentioned silicon-containing film forming composition above a substrate to form a coating film; and
heating the coating film.

In the present invention, “above a substrate” includes a case where the composition is directly applied on a substrate and a case where the composition is applied on a substrate via one or more intermediate layers.

The coating method can be freely selected from conventionally known methods such as spin coating method, dip method, spray method, transfer method, inkjet method, roll coating, bar coating, brush coating, doctor coating, flow coating, and slit coating. Further, as the substrate to which the composition is applied, an appropriate substrate such as a silicon substrate, a glass substrate, or a resin film can be used. Various kinds of semiconductor device and the like can be formed on these substrates, if necessary. If the substrate is a film, gravure coating is also available. If desired, a drying step can be separately set up after forming the coating film. Further, the coating step can be repeated once, twice, or more as needed to obtain a desired film thickness of the coating film.

After forming a coating film using the composition according to the present invention, the coating film can be prebaked (heat-treated) for the purpose of drying the coating film and decreasing the residual amount of the solvent.

The prebaking step can be conducted in an oxidizing or a non-oxidizing atmosphere, preferably at a temperature of 50 to 400° C., for 10 seconds to 60 minutes in a case of a hot plate and for 1 to 120 minutes in a case of a clean oven.

After forming a coating film using the composition according to the present invention, the coating film can be irradiated with light or electron beam, preferably electron beam, before heating for curing. In the electron beam irradiation, acceleration voltage is preferably 20 to 200 kv, and irradiation dose is preferably 5,000 to 50,000 kGy. The light irradiation is performed by irradiates light having a peak wavelength of preferably 248 to 436 nm, more preferably 248 to 405 nm. The irradiation intensity is preferably 10 to 800 mW/cm2, more preferably 40 to 600 mW/cm2, and the irradiation time is preferably 30 to 3,500 seconds, more preferably 50 to 3,000 seconds.

Then, the coating film, which is prebaked, electron beam-irradiated and/or light-irradiated, if necessary, is heated and cured in a non-oxidizing atmosphere, an oxidizing atmosphere and/or an ammonia atmosphere, thereby forming a silicon-containing film. The heating temperature is preferably 200 to 1,000° C., more preferably 300° C. or higher. The heating time is not particularly limited, and is preferably 0.001 second to 24 hours. Flash annealing can be used for the heating. Normally, it takes several seconds to several hours until a film reaches a desired temperature from the temperature before heating.

The non-oxidizing atmosphere means an atmosphere having an oxygen concentration of 1 ppm or less and a dew point of −76° C. or lower. Preferably, a gas atmosphere of N2, Ar, He, Ne, H2, or a mixture of two or more of any of these is used.

The oxidizing atmosphere means that the oxygen partial pressure is 20 to 101 kPa, preferably 40 to 101 kPa, and more preferably 1.5 to 80 kPa of steam partial pressure is contained, when the total pressure is 101 kPa.

In addition, when the heating is performed at high temperature (for example, a temperature exceeding 600° C.) in an atmosphere containing steam, there is a concern that the other elements would be adversely affected if other elements such as electronic devices are exposed to the heat treatment at the same time. In such a case, this heating step can be divided into two or more steps (more preferably three or more steps). For example, the coating film is heated first in a steam-containing atmosphere at low temperature (for example, in a temperature range of 200 to 400° C.), then heated in a steam-containing atmosphere at relatively low temperature (for example, in a temperature range of 300 to 600° C.), and heated at high temperature (for example, in a temperature range of 400 to 800° C.) in a steam-free atmosphere.

Any gas can be used as a component other than steam (hereinafter, referred to as the dilution gas) in an atmosphere containing steam, and examples thereof include air, oxygen, nitrogen, nitrogen oxide, ozone, helium and argon. Considering the film quality of the silicon-containing film, it is preferable to use oxygen as the dilution gas.

The ammonia atmosphere means that the ammonia partial pressure is 20 to 101 kPa, preferably 25 to 80 kPa, when the total pressure is 101 kPa.

The silicon-containing film according to the present invention can be made into an amorphous silicon film by heating in a non-oxidizing atmosphere. The cured film is an amorphous silicon film, which is confirmed with no diffraction peak corresponding to a crystalline Si observed by X-ray diffraction (XRD).

The silicon-containing film according to the present invention can be made into a siliceous film by heating in an oxidizing atmosphere. In the present invention, the siliceous film means a film comprising oxygen atoms and silicon atoms, which have a ratio of the number of oxygen atoms to the number of silicon atoms (O/Si) of 1.20 to 2.50, preferably 1.40 to 2.50, and more preferably 1.60 to 2.45. The siliceous film can contain other atoms such as hydrogen, nitrogen and carbon.

The silicon-containing film according to the present invention can be made into a silicon nitride film by heating in an ammonia atmosphere. In the present invention, the silicon nitride film is a film in which the ratio of the number of nitrogen atoms to the number of silicon atoms (N/Si) is 0.2 to 2.0, and preferably 0.4 to 1.6. The silicon nitride film can contain other atoms such as hydrogen and oxygen.

The film thickness of the formed silicon-containing film is not particularly limited, but is preferably 20 to 500 nm, and more preferably 20 to 300 nm.

A silicon-containing film having high planarity can be formed by using the composition according to the present invention. The silicon-containing film formed has low residual stress.

The method for manufacturing an electronic device according to the present invention comprises the above-mentioned manufacturing method. Preferably, the electronic device according to the present invention is a semiconductor device, a solar cell chip, an organic light emitting diode, or an inorganic light emitting diode. A preferred embodiment of the electronic device of the present invention is a semiconductor devices.

Hereinafter, the present invention is explained with reference to Examples. These Examples are for explanation and are not intended to limit the scope of the present invention.

The steps of synthesizing the polysilane and preparing the composition in the following Examples and Comparative Examples are all conducted in a glove box controlled to have an oxygen concentration of 0.1 ppm or less and a dew point temperature of −76.0° C. or lower under a nitrogen gas atmosphere.

### Example 1

A stirrer tip is placed in a 9 mL screw tube, and 246.4 mg of cyclohexasilane is added thereto and stirred using a stirrer. 0.7 J/cm² of ultraviolet ray having a wavelength of 365 nm using a LED lamp as a light source is irradiated. After the ultraviolet ray irradiation, 68.1 mg of tetravinylsilane and 31.4 mg of perhydropolysilazane is added thereto and stirred for 12 hours using a stirrer. After stirring, 2,957 mg of cyclooctane is added and stirred for 3 minutes, and filtration is conducted using a 0.2 μm PTFE filter (DISMIC-13JP, manufactured by Advantec) to prepare a composition of Example 1.

The mass average molecular weight of the polymer having a polysilane skeleton is 4,800. The mass average molecular weight (Mw) is measured by the gel permeation chromatography (GPC) based on polystyrene. GPC is measured using Alliance (trademark) e2695 type high-speed GPC system (Japan Waters K.K.) and a GPC column for organic solvent, Shodex KF-805L (Showa Denko K.K.). The measurement is conducted using monodispersed polystyrene as a standard sample and cyclohexene as a developing solvent, under the measuring conditions of a flow rate of 0.6 ml/min and a column temperature of 40° C., and then Mw is calculated as a relative molecular weight to the standard sample.

### Examples 2 to 8, Comparative Example 1

The compositions of Examples 2 to 8 and Comparative Example 1 are prepared in the same manner as in Example 1 except that the components and conditions shown in Table 1 are used.

The Mw of the obtained polymer having a polysilane skeleton is measured in the same manner as above, and the results are described in Table 1.

TABLE 1

| | (I) Polymer having a polysilane skeleton | | | | | (II) Silicon | | | | | |
|---|---|---|---|---|---|---|---|---|---|---|---|
| | | | Ultraviolet | | | compound having an | | | | | |
| | Polysilane compound | | ray irradiation | | Mw | unsaturated hydrocarbon | | (III) Solvent | | (IV) Polysilazane | |
| Example 1 | cyclohexasilane | 246.4 | 365 nm | 0.7 | 4,800 | tetravinylsilane | 68.1 | cyclooctane | 2957 | perhydropolysilazane | 31.4 |
| | | mg | (LED) | J/cm² | | | mg | | mg | | mg |
| Example 2 | cyclohexasilane | 246.4 | 365 nm | 0.7 | 5,350 | tetravinylsilane | 38.4 | cyclooctane | 1879 | perhydropolysilazane | 15.5 |
| | | mg | (LED) | J/cm² | | | mg | | mg | | mg |
| Example 3 | cyclohexasilane | 246.4 | 365 nm | 0.7 | 5,630 | tetravinylsilane | 117.9 | cyclooctane | 1813 | perhydropolysilazane | 31.4 |
| | | mg | (LED) | J/cm² | | | mg | | mg | | mg |
| Example 4 | cyclohexasilane | 246.4 | 365 nm | 0.7 | 5,180 | tetravinylsilane | 13.6 | cyclooctane | 2096 | perhydropolysilazane | 41.7 |
| | | mg | (LED) | J/cm² | | | mg | | mg | | mg |
| Example 5 | cyclohexasilane | 246.4 | 365 nm | 0.7 | 5,200 | tetravinylsilane | 39.3 | cyclooctane | 2999 | perhydropolysilazane | 31.4 |
| | | mg | (LED) | J/cm² | | | mg | | mg | | mg |
| Example 6 | cyclohexasilane | 246.4 | 365 nm | 0.5 | 4,620 | dimethyldivinylsilane | 21.0 | cyclooctane | 2136 | — | — |
| | | mg | (LED) | J/cm² | | | mg | | mg | | |
| Example 7 | cyclohexasilane | 246.4 | 365 nm | 0.7 | 4,800 | tetravinylsilane | 68.1 | cyclooctane | 2957 | perhydropolysilazane | 31.4 |
| | | mg | (LED) | J/cm² | | | mg | | mg | | mg |
| Example 8 | cyclohexasilane | 246.4 | 365 nm | 0.7 | 4,800 | tetravinylsilane | 68.1 | cyclooctane | 2957 | perhydropolysilazane | 31.4 |
| | | mg | (LED) | J/cm² | | | mg | | mg | | mg |
| Comparative | cyclohexasilane | 268.7 | 365 nm | 8.4 | 8,650 | — | — | cyclooctane | 1226 | perhydropolysilazane | 17.3 |
| Example 1 | | mg | (LED) | J/cm² | | | | | mg | | mg |

### [Formation of a Silicon-Containing Film]

The composition of Example 1 prepared above is applied on a Si substrate in a nitrogen atmosphere using a spin coater to form a coating film. The obtained coating film is heated on a hot plate at 400° C. for 15 minutes in a nitrogen atmosphere to obtain a silicon-containing film.

Using the compositions of Examples 2 to 8 and Comparative Examples 1 prepared above, heating is conducted in the same manner as above, except that the heating conditions are changed to the conditions described in Table 2.

Using the compositions of Examples 1 to 6 and Comparative Example 1, measurement of the FT-IR spectrum of the silicon-containing film formed is conducted at room temperature using FTIR-6100 (JASCO Corporation), and it is confirmed that the obtained silicon-containing film is an amorphous silicon film.

In the case of using the composition of Example 7, it is confirmed by the measurement of the FT-IR spectrum that the obtained silicon-containing film is a siliceous film.

In the case of using the composition of Example 8, it is confirmed by the measurement of the FT-IR spectrum that the obtained silicon-containing film is a silicon nitride film.

When the compositions of Examples 1 to 8 and Comparative Example 1 are used, the coatability is good, a coating film can be uniformly formed on a substrate, and a uniform silicon-containing film can be formed without peeling from the substrate even during heating.

The heating condition of Example 5 includes electron beam irradiating wherein 32,000 kGy of electron beam is irradiated with a line irradiation-type low energy electron beam irradiation device EES-30L-MPM01 (Hamamatsu Photonics) at room temperature at nitrogen atmosphere at 70 kV of acceleration voltage at 7.6 mA of tubular current to the coating film of Example 5 on a silicon substrate, and then heating at 400° C. on a hot plate for 15 minutes at nitrogen atmosphere, to obtain a silicon-containing film.

### [Film Thickness]

The film thickness of the obtained silicon-containing film is measured using a spectroscopic ellipsometer M-2000V (J.A. Woollam). For the film thickness, it is measured at 8 points excluding the central part on the wafer, and the average value thereof is used as the film thickness. The results obtained are described in Table 2.

### [Refractive Index]

The refractive index of the obtained silicon-containing film is measured at a wavelength of 633 nm using a spectroscopic ellipsometer M-2000V (J.A. Woollam). The results obtained are described in Table 2.

### [Residual Film Stress]

The residual film stress is measured at thin film stress measurement system FLX-3300-T (Toho Technology Inc.). The results obtained are described in Table 2.

TABLE 2

| | Film | Reflactive | Residual | |
|---|---|---|---|---|
| | thickness | index | stress | |
| | (nm) | @633 nm | (MPa) | Heating condition |
| Example 1 | 176 | 2.02 | 7 | nitrogen atmosphere 400° C. 15 min |
| | | | tensile | |
| Example 2 | 155 | 2.05 | 56 | nitrogen atmosphere 400° C. 15 min |
| | | | tensile | |
| Example 3 | 170 | 1.99 | −21 | nitrogen atmosphere 400° C. 15 min |
| | | | compressive | |
| Example 4 | 160 | 2.41 | 98 | nitrogen atmosphere 400° C. 15 min |
| | | | tensile | |
| Example 5 | 149 | 2.01 | 70 | after electron beam irradiation, |
| | | | tensile | nitrogen atmosphere 400° C. 15 min |
| Example 6 | 208 | 2.88 | 44 | nitrogen atmosphere 400° C. 15 min |
| | | | tensile | |
| Example 7 | 193 | 1.46 | 32 | water-vapor atomosphere 400° C. 15 min |
| | | | tensile | |
| Example 8 | 152 | 1.79 | 156 | ammonia atmosphere 400° C. 15 min |
| | | | tensile | |
| Comparative | 202 | 3.18 | 320 | nitrogen atmosphere 400° C. 15 min |
| Example 1 | | | tensile | |

1. A silicon-containing film forming composition comprising:
(I) a polymer having a polysilane skeleton comprising a repeating unit represented by the formula (ia): 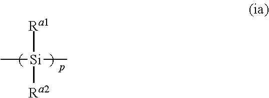
wherein
R^{a1} and R^{a2} are each independently a single bond, hydrogen, halogen, C1-6 alkyl, C6-10 aryl or —SiR^{A}₃ wherein each R^{A} is independently hydrogen or C1-8 alkyl, and
p is an integer of 5 or more;
(II) a silicon compound having an unsaturated hydrocarbon bond; and
(III) a solvent.

2. The composition according to claim 1, wherein the polymer having a polysilane skeleton (I) further comprises a repeating unit represented by the formula (ib): 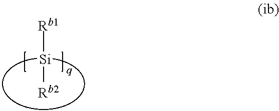
wherein
R^{b1} and R^{b2} are each independently a single bond, hydrogen, halogen, C1-6 alkyl, C6-10 aryl or —SiR^{B}₃ wherein each RB is independently hydrogen or C1-8 alkyl, provided that at least one of R^{b1} and R^{b2} is a single bond, and
q is an integer of 5 or more.

3. The composition according to claim 1, further comprising (IV) a polysilazane.

4. The composition according to claim 1, wherein the silicon compound having an unsaturated hydrocarbon bond (II) is represented by the formula (ii): 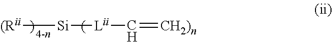
wherein
Lⁱⁱ is each independently a single bond or C1-5 alkylene,
Rⁱⁱ is each independently hydrogen or C1-5 alkyl, and
n is 1, 2, 3 or 4.

5. The composition according to claim 1, wherein the silicon compound having an unsaturated hydrocarbon bond (II) is at least one selected from the group consisting of divinylsilane, trivinylsilane, tetravinylsilane, methyldivinylsilane, dimethyldivinylsilane, methyltrivinylsilane, diallylsilane, triallylsilane, diallylmethylsilane, diallyldimethylsilane, triallylmethylsilane, and tetraallylsilane.

6. The composition according to claim 1, wherein the relative dielectric constant of the solvent (III) is 3.0 or less.

7. The composition according to claim 1, wherein the polymer having a polysilane skeleton (I) is a polymer of a polysilane compound comprising 5 or more silicon.

8. The composition according to claim 7, wherein the polysilane compound comprises a cyclic polysilane.

9. The composition according to claim 8, wherein the cyclic polysilane is represented by the following formula (ib′): 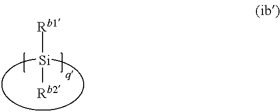
wherein
Rb1′ and Rb2′ are each independently hydrogen, halogen, C1-6 alkyl, C6-10 aryl or —SiR^{B′}₃ wherein each R^{B′} is independently hydrogen or C1-8 alkyl, and
q′ is an integer of 5 or more.

10. The composition according to claim 8, wherein the cyclic polysilane is at least one selected from the group consisting of silylcyclopentasilane, silylcyclohexasilane, disilylcyclohexasilane, cyclopentasilane and cyclohexasilane.

11. The composition according to one or more of claim 7, wherein the polysilane compound is at least one selected from the group consisting of neopentasilane, hexasilane, 3-silylpentasilane, 2,2-disilyltetrasilane, heptasilane, tetrasilyltetrasilane and hexasilylpentasilane.

12. A method for manufacturing a silicon-containing film comprising:
applying the composition according to claim 1 on a substrate to form a coating film, and
heating the coating film.

13. The method according to claim 12, wherein the step of heating the coating film is performed in a non-oxidizing atmosphere.

14. The method according to claim 12, wherein the step of heating the coating film is performed in an oxidizing atmosphere.

15. The method according to claim 12, wherein the step of heating the coating film is performed in an ammonia atmosphere.

16. The method according to claim 12, wherein after forming the coating film, the coating film is exposed to light having a peak wavelength of 248 to 436 nm.

17. The method according to claim 12, wherein after forming the coating film and before heating the coating film, the film is exposed to an electron beam.

18. The method according to claim 12, wherein the step of heating the coating film is performed at 200 to 1,000° C.

19. A method for manufacturing an electronic device, comprising incorporating the silicon-containing film prepared according to the method according to claim 12 in the electronic device.
